(19) United States
(12) Patent Application Publication
(10) Pub. No.: US 2010/0112777 A1
(43) Pub. Date: May 6, 2010

(54) METHOD OF FORMING A SEMICONDUCTOR DEVICE

(76) Inventors: HanJin LIM, Seoul (KR); Seokwoo Nam, Seongnam-si (KR); Junghee Chung, Suwon-si (KR); KyoungRyul Yoon, Goyang-si (KR); Jong-Bom Seo, Seoul (KR); Jun-Noh Lee, Hwaseong-si (KR); Sunghoon Bae, Hwaseong-si (KR)

Correspondence Address: F. CHAU & ASSOCIATES, LLC, 130 WOODBURY ROAD, WOODBURY, NY, 11797, US

(21) Appl. No.: 12/612,320

(22) Filed: Nov. 4, 2009

(30) Foreign Application Priority Data
Nov. 6, 2008 (KR) 10-2008-0109858

(51) Int. Cl. H01L 21/02

(52) U.S. Cl. 438/399; 257/E21.011

(57) ABSTRACT

A method of forming a semiconductor device includes forming a bottom electrode having a top surface and a side surface on a semiconductor substrate, performing a tilted ion implantation process to supply ions to the top surface of the bottom electrode and to a portion of the side surface of the bottom electrode, and forming a dielectric layer on the bottom electrode. The formation of the dielectric layer is delayed at the ion-supplied top surface of the bottom electrode and the ion-supplied portion of the side surface of the bottom electrode.

### CROSS-REFERENCE TO RELATED APPLICATION

This application claims priority to Korean Patent Application No. 10-2008-0109858, filed on Nov. 6, 2008, the disclosure of which is hereby incorporated by reference herein in its entirety.

### BACKGROUND

1. Technical Field

The present disclosure relates to methods of forming a semiconductor device and, more specifically, to methods of forming a semiconductor device including a capacitor.

2. Description of Related Art

A DRAM device may include a cell array and a peripheral circuit. The cell array is a collection of cells in which data may be stored. The peripheral circuit may be configured to transmit data to the exterior with rapid precision. A memory cell of the DRAM device may include a transistor and a capacitor. The transistor may function as a switch and store data. A significant parameter of a DRAM device may be the capacitance of a cell capacitor which stores data. With the recent trend toward high integration of semiconductor devices, their minimum feature sizes continue to shrink. Therefore, a technology for integrating a capacitor having minimized capacitance into a smaller area has become a core technology for DRAM devices.

### SUMMARY

In accordance with an embodiment of the present invention, a method of forming a semiconductor device is provided. The method includes forming a bottom electrode having a top surface and a side surface on a semiconductor substrate, performing a tilted ion implantation process to supply ions to the top surface of the bottom electrode and to a portion of the side surface of the bottom electrode, and forming a dielectric layer on the bottom electrode. The formation of the dielectric layer is delayed at the ion-supplied top surface of the bottom electrode and the ion-supplied portion of the side surface of the bottom electrode.

In some embodiments, the tilted ion implantation process may use gas containing at least one selected from the group consisting of nitrogen, boron, and a combination thereof.

In some embodiments, the dielectric layer may be formed after performing the tilted ion implantation process. Forming the dielectric layer may include performing an atomic layer deposition (ALD) process.

In some embodiments, the bottom electrode may include a first region to which the ions are supplied and a second region to which the ions are not supplied. The first region may include a top surface and a side upper portion of the bottom electrode, and the second region may include a lower portion of the bottom electrode. During the ion implantation process, a tilt may be adjusted to extend the first region

In some embodiments, the bottom electrode may have a cylindrical or pillar-type structure including the top surface and the side surface. The bottom electrode may include at least one selected from the group consisting of: metal such as aluminum (Al), copper (Cu) or tungsten (W); metal nitride such as titanium nitride (TiN), titanium aluminum nitride (TiAlN), titanium silicon nitride (TiSiN) or tantalum nitride (TaN); and noble metal such as ruthenium (Ru), Iridium (Ir) or platinum (Pt).

In some embodiments, the method may further comprise forming a top electrode to cover the bottom electrode.

In accordance with another embodiment of the present invention, a method of faulting a semiconductor device is provided. The method includes forming a bottom electrode on a semiconductor substrate. The bottom electrode has a first region including an inner surface, an outer surface and a top surface connecting the inner surface and the outer surface with each other and a second region which includes a lower portion of the bottom electrode. The method further includes performing a tilted ion implantation process by supplying ions to the first region of the bottom electrode. The tilted ion implantation process is performed using a gas containing at least one selected from the group consisting of nitrogen (N), boron (B) and a combination thereof, and the ions are not supplied to the second region of the bottom electrode by the tilted ion implantation process. The method further includes forming a dielectric layer to uniformly cover the bottom electrode. During the tilted ion implantation process, an amount of ions is supplied to upper portions of the top surface, the inner surface and the outer surface of the first region of the bottom electrode which is greater than an amount of ions supplied to lower portions of the inner surface and the outer surface of the first region of the bottom electrode and the formation of the dielectric layer is more delayed at the upper portion of the inner surface and the outer surface of the first region of the bottom electrode than at the lower portion of the inner surface of the first region of the bottom electrode. In addition, the method further includes forming a top electrode covering the bottom electrode.

### BRIEF DESCRIPTION OF THE DRAWINGS

Embodiments of the present invention can be understood in more detail from the following description taken in conjunction with the accompanying the drawings, in which:

FIGS. 1 to 7 are cross-sectional views illustrating a method of forming a semiconductor device according to an embodiment of the present invention.

FIG. 8A is an enlarged view of a region M shown in FIG. 5.

FIGS. 8B and 8C are enlarged views of the region M, which illustrate formation of a dielectric layer shown in FIG. 6.

FIG. 8D is a flowchart illustrating a mechanism for formation of a dielectric layer according to an embodiment of the present invention.

FIGS. 9 to 12 are cross-sectional views illustrating a method of forming a semiconductor device according to a modified embodiment of the present invention.

FIGS. 13 to 15 are cross-sectional views illustrating a method of forming a semiconductor device according to an embodiment of the present invention.

FIG. 16 illustrates a memory card system including a semiconductor device according to an embodiment or modified embodiment of the present invention.

FIG. 17 illustrates a block diagram illustrating an electronic device including a semiconductor device according to an embodiment or modified exemplary embodiment of the present invention.

### DETAILED DESCRIPTION OF THE EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

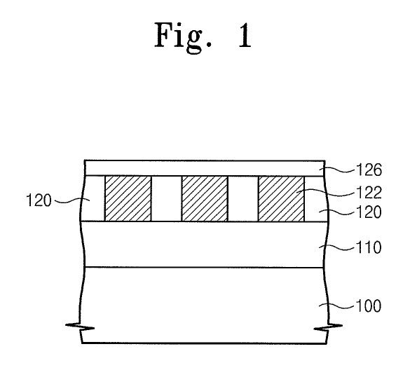

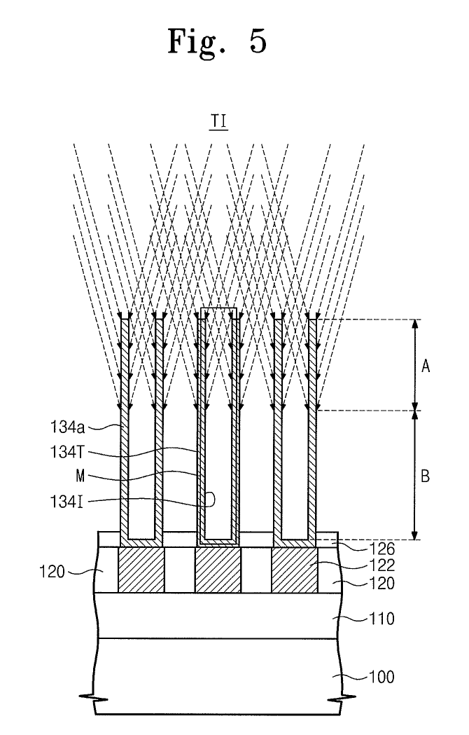

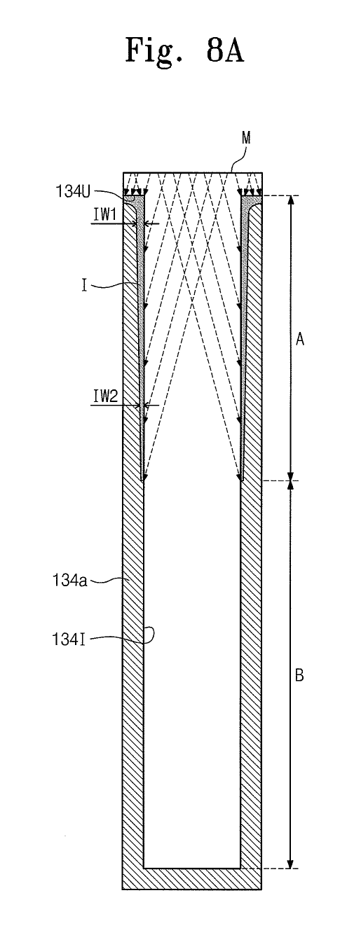

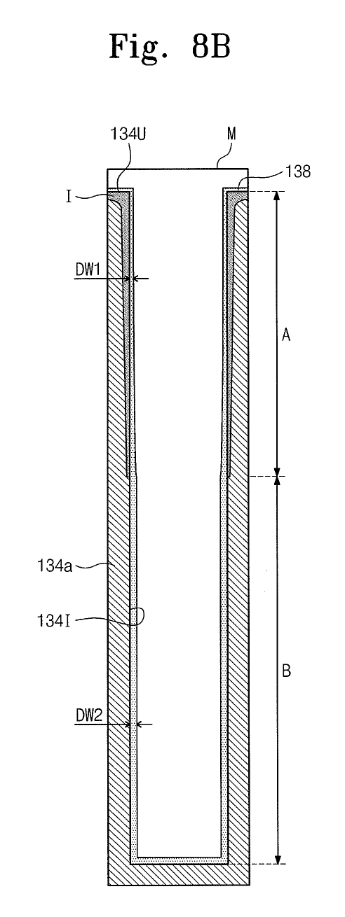

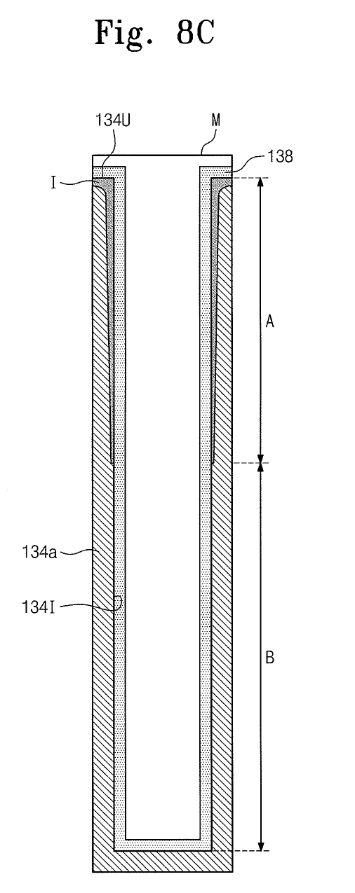

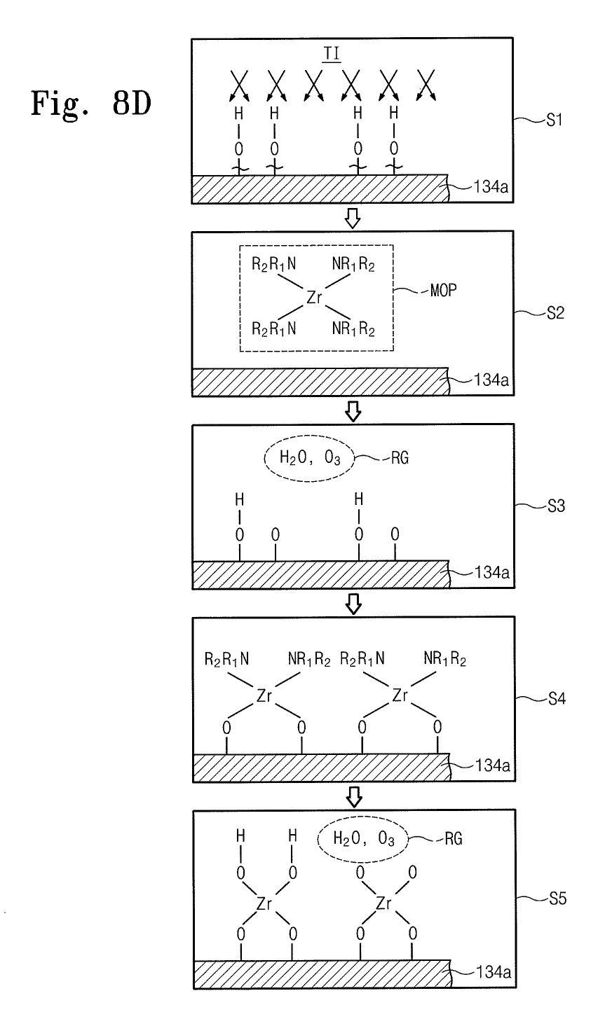

FIGS. 1 to 7 are cross-sectional views illustrating a method of forming a semiconductor device according to some embodiments of the present invention, and FIG. 8A is an enlarged view of a region M shown in FIG. 5.

Referring to FIG. 1, a first interlayer dielectric 110 may be formed on a semiconductor substrate 100. The semiconductor substrate 100 may be provided with an impurity region having electrical conductivity such as a source region. The first interlayer dielectric 110 may be, for example, a silicon oxide layer. The first interlayer dielectric 110 may include a conductor electrically connected to the impurity region.

A second interlayer dielectric 120 may be formed on the first interlayer dielectric 110. The second interlayer dielectric 120 may be, for example, a silicon oxide layer. A contact plug 122 may be formed to be electrically connected to the conductor through the second interlayer dielectric 120. A mask layer 126 may be formed on the second interlayer dielectric 120. The mask layer 126 may be, for example, a silicon nitride layer.

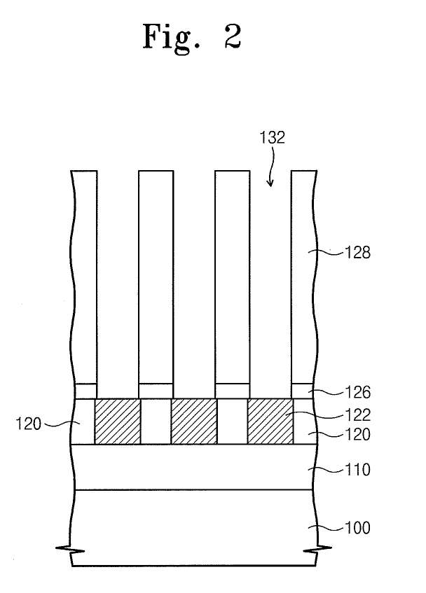

Referring to FIG. 2, a molding layer 128 may be formed on the mask layer 126. The molding layer 128 may be formed by means of, for example, a chemical vapor deposition (CVD) process or a spin-on-glass (SOG) process. The molding layer 128 may contain, for example, a silicon oxide-based material.

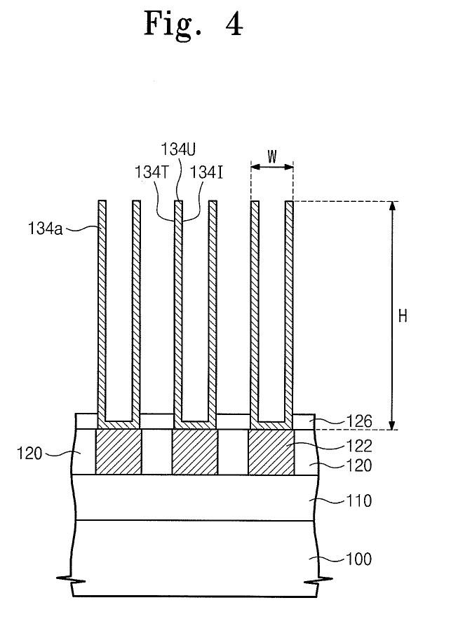

The molding layer 128 and the mask layer 126 are patterned to form a hole 132 therethrough. The hole 132 may be formed to expose a top surface of the contact plug 122. The mask layer 126 penetrated by the hole 132 may serve to support a bottom electrode (134a in FIG. 4) that will be formed in a subsequent process.

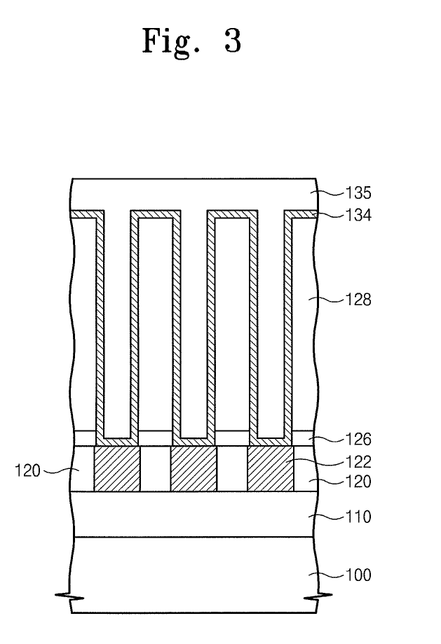

Referring to FIG. 3, a conductive layer 134 may be formed at the hole 132. The conductive layer 134 may be formed by means of, for example, a physical vapor deposition (PVD) process, a CVD process or an atomic layer deposition (ALD) process. The conductive layer 134 may contain, for example, at least one selected from the group consisting of: metal such as aluminum (Al), copper (Cu) or tungsten (W); metal nitride such as titanium nitride (TiN), titanium aluminum nitride (TiAlN), titanium silicon nitride (TiSiN) or tantalum nitride (TaN); and noble metal such as ruthenium (Ru), Iridium (Ir) or platinum (Pt). The conductive layer 134 may be uniformly formed on an exposed top surface of the contact plug 122 and sidewalls of the hole 132.

A sacrificial layer 135 may be formed on the conductive layer 134 to fill the hole 132. The sacrificial layer 135 may be formed by means of, for example, a CVD process or an SOG process. The sacrificial layer 135 may contain a material having beneficial fluidity such as, for example, silicon oxide or a photoresist.

Referring to FIG. 4, a bottom electrode 134a may be formed by, for example, successively planarizing the sacrificial layer (135 in FIG. 3) and the conductive layer (134 in FIG. 3) down to a top surface of the molding layer (138 in FIG. 3). The sacrificial layer (135 in FIG. 3) may be planarized by means of, for example, a chemical mechanical polishing (CMP) process or a dry etch-back process. The bottom electrode 134a may have an inner surface 134I, an outer surface 134T, and a top surface 134U connecting the inner surface 134I and the outer surface 134T with each other. The bottom electrode 134a may be, for example, a cylindrical storage electrode. The bottom electrode 134a may be a high-aspect-ratio electrode. The aspect ratio may be a ratio of height H of the bottom electrode 134a to width W of the bottom electrode 134a.

The inner surface 134I and the outer surface 134T of the bottom electrode 134a may be exposed by removing the molding layer 128 and the sacrificial layer 135. The molding layer 128 and the sacrificial layer 135 may be removed by means of, for example, a wet etching process using an etchant containing, for example, hydrofluoric acid (HF).

Referring to FIGS. 5 and 8A, a tilted ion implantation process TI is performed for the bottom electrode 134a. The tilted ion implantation process may use, for example, a gas containing at least one selected from the group consisting of nitrogen (N), boron (B), and a combination thereof.

The bottom electrode 134a may include a first region “A” and a second region “B”. The first region “A” may be a region to which ions are supplied, and the second region “B” may be a region to which the ions are not supplied. In the first region “A”, a third region “I” may be a region which relatively exhibits the size of the amount of the ions supplied to the first region “A”. For example, upper width IW1 of a portion of the third region “I” may be greater than lower width IW2 of a portion of the third region “I”. That is, the amount of ions supplied to an upper portion of the inner surface 134I in the first region “A” may be greater than that of ions supplied to a lower portion of the inner surface 134I in the first region “A”. This is because the amount of ions supplied to upper portions of the top surface 134U, the inner surface 134I, and the outer surface 134T of the first region “A” may be greater than that of ions supplied to lower portions of the inner surface 134I and the outer surface 134T of the first region “A”. More ions may be supplied to lower portions of the inner surface 134I and the outer surface 134T of the bottom electrode 134a by adjusting a tilt during the ion implanting process TI. Thus, the first region “A” may be formed to have a larger area.

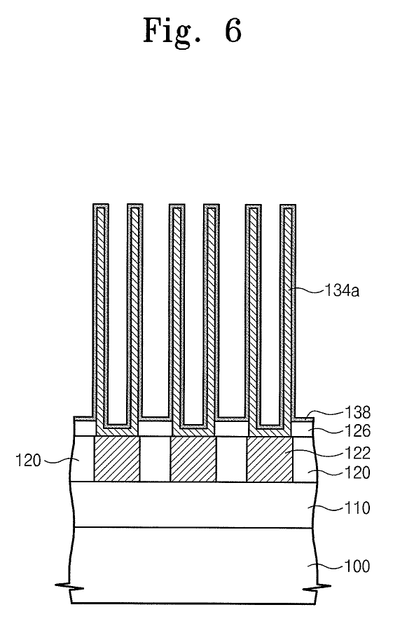

Referring to FIG. 6, a dielectric layer 138 may be formed to cover the bottom electrode 134a. The dielectric layer 138 may be formed by means of, for example, a CVD process or an ALD process.

The formation of the dielectric layer 138 may be described by exemplifying an ALD process. FIGS. 8B and 8C are enlarged views of a region M, which illustrate formation of the dielectric layer 138 shown in FIG. 6, respectively. FIG. 8D is a flowchart illustrating a mechanism for formation of a dielectric layer according to some exemplary embodiments of the present invention.

Referring to FIG. 8A and S1 in FIG. 8D, the bottom electrode 134a may include, for example, a hydroxyl radical (OH) adsorbed to inner, outer, and top surfaces 134I, 134T, and 134U of the bottom electrode 134a. Due to the tilted ion implantation process TI, the hydroxyl radical may be separated from the inner, outer, and top surfaces 134I, 134T, and 134U.

Referring to FIG. 8A and S2 in FIG. 8D, a source gas may be supplied onto the bottom electrode 134a. The source gas may contain, for example, a metal-organic precursor (MOP) such as tetrakis(ethylmethylamino) zirconium (Zr[N(CH₃)C₂H₅]₄; TEMAZ). The dielectric layer 138 may be formed through, for example, chemisorption of the metal-organic precursor to the hydroxyl radical (OH). However, chemisorption of the metal-organic precursor to the inner surface 134I, the outer surface (134T in FIG. 5), and the top surface 134U of the first region “A” may be delayed as the hydroxyl radical is separated due to the ion implantation process TI.

That is, formation of the dielectric layer 138 may be delayed at the inner, outer, and top surfaces 134I, 134T, and 134U of the first region “A”. Especially, the amount of ions supplied to upper portions of the inner and top surfaces 134I and 134U of the first region “A” may be greater than that of ions supplied to a lower portion of the inner surface 134I of the first region “A”. Therefore, the formation of the dielectric layer 138 may be more delayed at the upper portion of the inner and outer surfaces 134I and 134T of the first region “A”. Width DW1 of a portion of the dielectric layer 138 in the first region “A” may be smaller than width DW2 of a portion of the dielectric layer 138 in the second region “B”.

Moreover, because the hydroxyl radical is separated from the inner, outer, and top surfaces 134I, 134T, and 134U of the first region “A”, the surface migration of the metal-organic precursor (MOP) may increase. Thus, the MOP may readily migrate to the lower portions of the inner and outer surfaces 134I and 134T of the second region “B” along the inner and outer surfaces 134I and 134T of the first region “A”.

Referring to FIG. 8B and S3 in FIG. 8D, reaction gas RG may be supplied onto the bottom electrode 134a after supplying the source gas. The reaction gas RG may, for example, contain vapor (H₂O) or ozone (O₃). The reaction gas RG may allow hydroxyl radical to be adsorbed to inner, outer, and top surfaces 134I, 134T, and 134U of a bottom electrode 134a.

Referring to FIG. 8C and S4 and S5 in FIG. 8D, the adsorbed hydroxyl radical and metal-organic precursor may be chemically bound to form a dielectric layer 138. In the early stage, the dielectric layer 138 may be grown better at the second region “B” than at the first region “A”. As a bottom electrode 134a in the first region “A” may receive metal-organic precursors more than a bottom electrode 134a at the second region “B”, the dielectric layer 138 may be grown better at the first region “A” than at the second region “B”.

According to some exemplary embodiments, a tilted ion implantation process TI is performed to prevent a dielectric layer 138 from overgrowing at upper portions of inner and outer surfaces 134I and 134T of a high-aspect-ratio bottom electrode 134a and a top surface 134U of the high-aspect-ratio bottom electrode 134a. The dielectric layer 138 may also be readily formed at bottom portions of the inner and outer surfaces 134I and 134T. Thus, the dielectric layer 138 may be formed to uniformly cover the inner, outer, and top surface 134I, 134T, and 134U of the bottom electrode 134a. That is, a step coverage characteristic of the dielectric layer 138 may be improved to provide a semiconductor device including a capacitor of improved reliability and electrical properties.

As mentioned above, the dielectric layer 138 may also be readily formed at the lower portions of the inner and outer surfaces 134I and 134T. Therefore, a process of forming the dielectric layer 138 may be conducted at a high temperature (e.g., 200 to 300 degrees centigrade) to remove impurities such as, for example, carbon (C) and hydrogen (H) contained in the dielectric layer 138. That is, degradation in step coverage characteristic of the dielectric layer 138 may be suppressed to improve the quality of the dielectric layer 138.

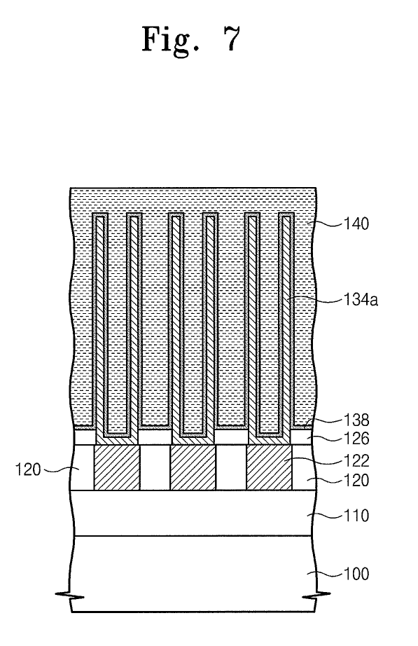

Referring to FIG. 7, a top electrode 140 may be formed to cover the bottom electrode 134a. The top electrode 140 may be formed by means of, for example, a chemical vapor deposition (CVD) process or a physical vapor deposition (PVD) process. The top electrode 140 may contain, for example, one selected from the group consisting of metal, metal nitride, and polysilicon. The top electrode 140 may contain, for example, titanium nitride, polysilicon or tungsten. The top electrode 140 may be, for example, a plate electrode of a capacitor.

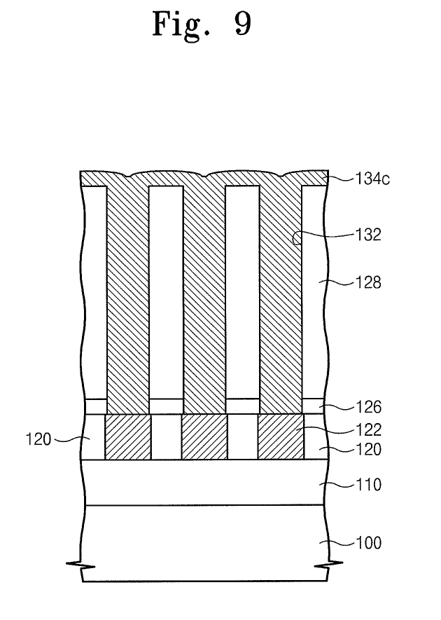

FIGS. 9 to 12 are cross-sectional views illustrating a method of forming a semiconductor device according to modified embodiments of the present invention. This method may be similar to the above-described method. Hence, duplicate technical features therebetween will be simply explained or not be explained for the convenience of description.

Referring to FIG. 9, a molding layer 128 including a hole 132 may be formed on a semiconductor substrate 100. The molding layer 128 may be formed by, for example, the same manner as described in FIGS. 1 and 2. A conductive layer 134c may be formed to fill the hole 132.

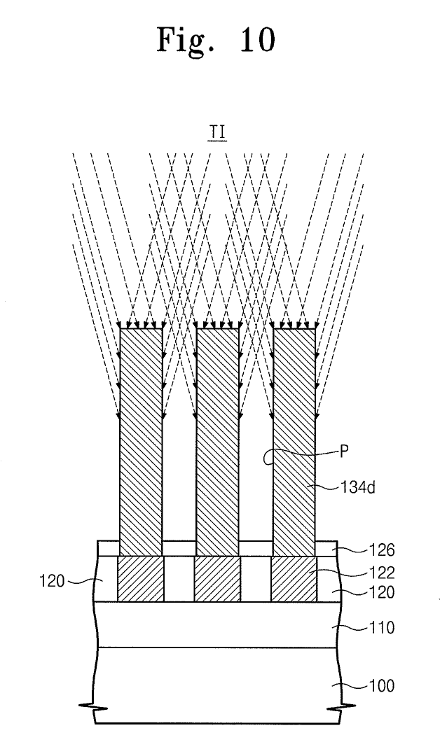

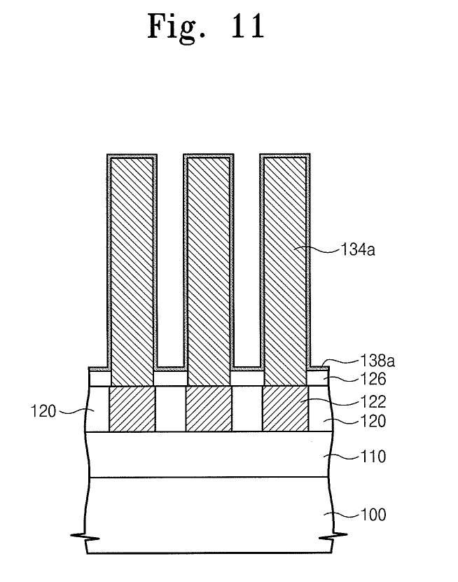

Referring to FIGS. 10 and 11, a bottom electrode 134d may be formed by planarizing the conductive layer (134c in FIG. 9) down to a top surface of the molding layer 128. The bottom electrode 134d may be, for example, a pillar-type storage electrode. A deep opening P is formed between respective bottom electrodes 134d. The opening P may be defined by a side surface of the bottom electrode 134d.

After performing a tilted ion implantation process for top and side surfaces of the bottom electrode 134d, a dielectric layer 138a may be formed on the bottom electrode 134d. According to the modified embodiments, a pillar-type storage electrode may be provided with a dielectric layer 138a having a uniform thickness. That is, technical features of embodiments of the present invention may be applied to any type of high-aspect-ratio bottom electrode. The bottom electrode may include, for example, a concave-hole structure or a stacked structure. While the technical features of embodiments of the present invention have been applied to DRAM devices, they may be applied to capacitors of non-memory devices.

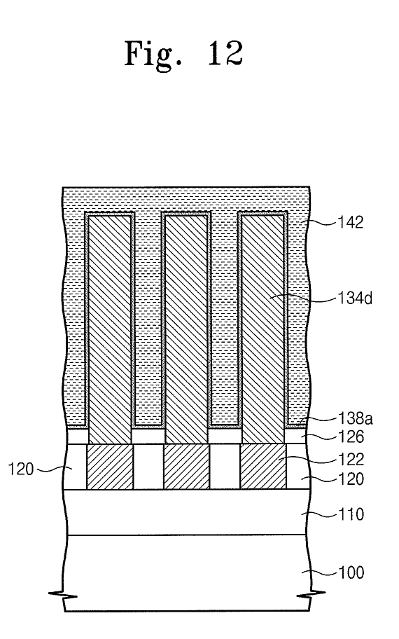

Referring to FIG. 12, a top electrode 142 may be formed on a bottom electrode 134d where the dielectric layer 138a is formed. The top electrode 142 may be, for example, a plate electrode of a capacitor.

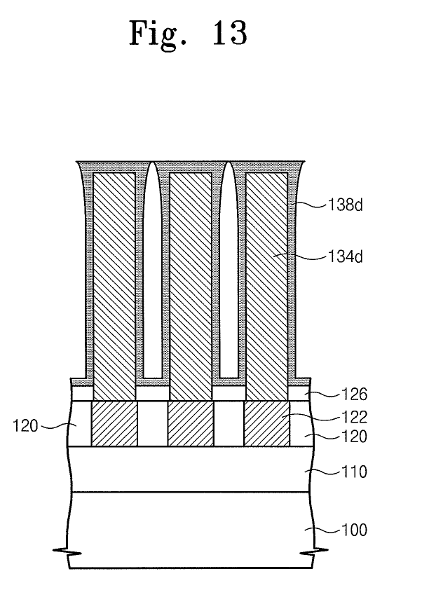

FIGS. 13 to 15 are cross-sectional views illustrating a method of forming a semiconductor device according to other embodiments of the present invention.

Referring to FIG. 13, a bottom electrode 134d having exposed top and side surfaces may be formed on a semiconductor substrate 100. The bottom electrode 134d may be, for example, a pillar-type storage electrode.

An insulating layer 138d may be formed on the bottom electrode 134d. The insulating layer 138d may be formed by means of, for example, a plasma enhanced chemical vapor deposition (PE-CVD) process or a plasma enhanced atomic layer deposition (PE-ALD) process. The insulating layer 138d may contain one selected from the group consisting of, for example, aluminum oxide (Al₂O₃), zirconium oxide (ZrO₂), hafnium oxide (HfO₂), tantalum pentoxide (Ta₂O₅), titanium oxide (TiO₂), strontium titanate (SrTiO₃), and barium strontium titanate (BaSrTiO₃). The insulating layer 138d may be formed to be thicker at an upper portion of a side surface and a top surface of the bottom electrode 134d having a high aspect ratio than at a lower portion of the side surface of the bottom electrode 134d.

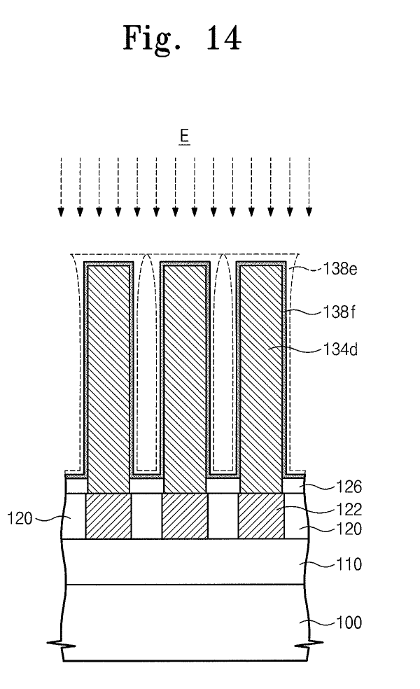

Referring to FIG. 14, a dielectric layer 138f may be formed by, for example, performing an etch process E for the insulating layer (138d in FIG. 13). The etch process E may be, for example, an anisotropic etch process. The etch process E may include, for example, a plasma dry etch process.

In other embodiments of the present invention, an insulating layer 138d on a side upper portion and a top surface of the bottom electrode 134d may have a higher position and a larger area than that on a lower portion of the bottom electrode 134d. Therefore, a dielectric layer 138f may be formed uniformly over the bottom electrode 134d. A dotted region 138e surrounding the dielectric layer 138f may be expressed with the amount etched.

The process of forming the insulating layer 138d and the etch process E may be, for example, repeatedly performed to uniformly form the dielectric layer 138f. In addition, for example, after performing the etch process E, an annealing process may be performed to cure a damaged dielectric layer 138f.

The process of forming the insulating layer 138d and the etch process E may be performed at one apparatus. For example, following removal of source gas and reaction gas after forming the insulating layer 138d at a CVD apparatus or an ALD apparatus, the etch process E may be performed by introducing an etching gas into the CVD apparatus or the ALD apparatus.

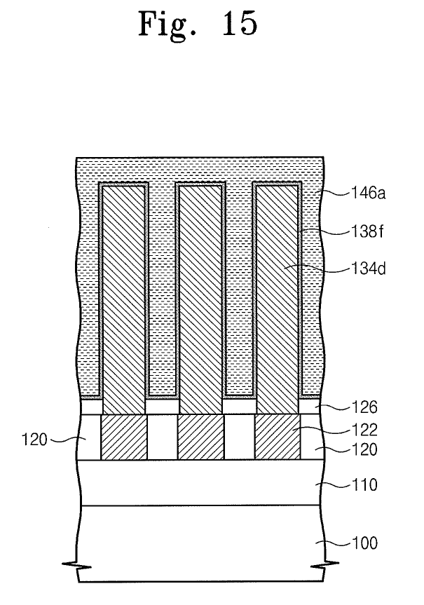

Referring to FIG. 15, a top electrode 146a may be formed to cover the bottom electrode 134d where the dielectric layer 138f is formed. The top electrode 146a may be, for example, a plate electrode of a capacitor.

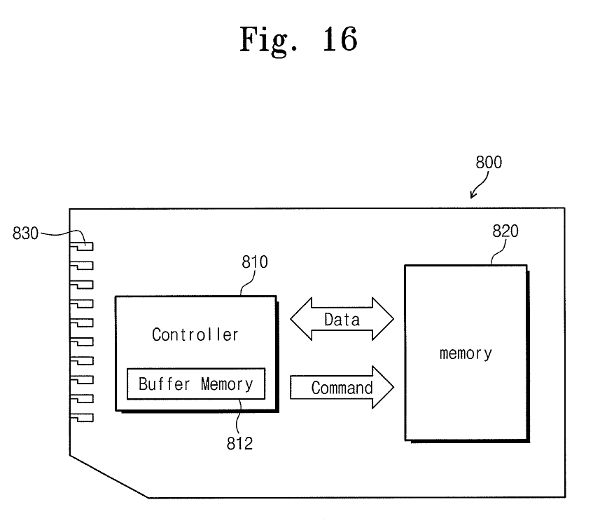

FIG. 16 illustrates a memory card system 800 including a semiconductor device according to some or modified embodiments of the present invention. As illustrated in FIG. 16, the memory system 800 may include a controller 810, a memory 820, and an interface 830.

For example, the memory 820 may be used to store a command executed by the controller 810 and/or user's data. The controller 810 and the memory 820 may be configured to exchange the command and/or the user's data. The interface 830 may serve to input/output data to/from the exterior. The controller 810 may include a buffer memory 812, which may be used to temporarily store data to be stored in the memory 820 or data read out of the memory 200. The buffer memory 812 may be used to temporarily store data processed in the controller 810. The buffer memory 812 is a random access memory (RAM) and may be embodied with a semiconductor device (e.g., DRAM) according to some or modified embodiments of the present invention.

The memory card system 800 may be, for example, a multimedia card (MMC), a secure digital card (SD) or a mobile data storage.

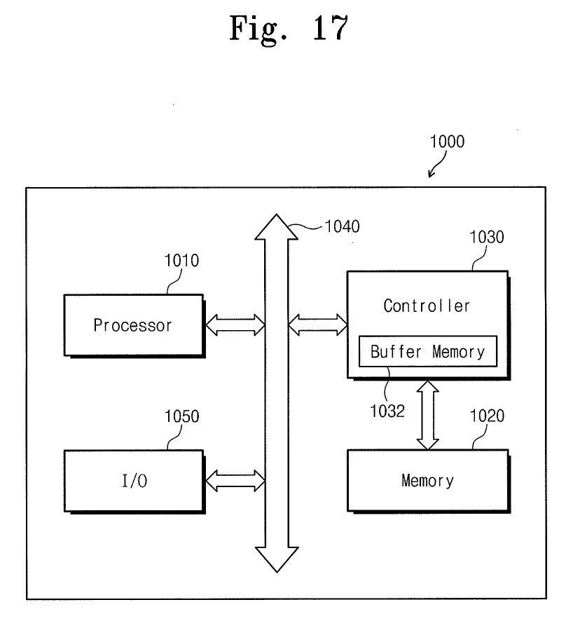

FIG. 17 is a block diagram illustrating an electronic device 100 including a semiconductor device according to some or modified embodiments of the present invention. As illustrated in FIG. 17, the electronic device 100 may include a processor 1010, a memory 1050, a controller 1030, and an input/output device (I/O) 1040. The processor 1010, the controller 1030, and the input/output device 1040 may be connected through a bus 1040. The processor 1010 may control all operations of the controller 1030. The controller 1030 may include a buffer memory 1032, which is a random access memory (RAM) and may be embodied with a semiconductor device (e.g., DRAM) according to some or modified embodiments of the present invention. The memory 1010 may be used to store data accessed through the controller 1030. It will be understood by a person of ordinary skill in the art that an additional circuit and control signals may be provided for detailed implementation and modification of embodiments of the present invention.

For example, the electronic device 1000 may be applied to, computer systems, wireless communication devices such as personal digital assistants (PDA), laptop computers, web tablets, wireless telephones, and mobile phones, digital music players, MP3 players, navigation systems, solid-state disks (SSD), household appliances or all devices capable of wirelessly receiving/transmitting information.

Having described embodiments of the present invention, it is further noted that it is readily apparent to those skilled in the art that various substitutions, modifications and changes may be made without departing from the scope and spirit of the invention which is defined by the metes and bounds of the appended claims.

What is claimed is:

1. A method of forming a semiconductor device, comprising:
forming a bottom electrode having a top surface and a side surface on a semiconductor substrate;
performing a tilted ion implantation process to supply ions to the top surface of the bottom electrode and to a portion of the side surface of the bottom electrode; and
forming a dielectric layer on the bottom electrode,
wherein the formation of the dielectric layer is delayed at the ion-supplied top surface of the bottom electrode and the ion-supplied portion of the side surface of the bottom electrode.

2. The method of claim 1, wherein the tilted ion implantation process uses a gas containing at least one selected from the group consisting of nitrogen, boron, and a combination thereof.

3. The method of claim 1, wherein forming the dielectric layer includes performing an atomic layer deposition (ALD) process.

4. The method of claim 1, wherein the bottom electrode includes a first region to which the ions are supplied and a second region to which the ions are not supplied, wherein the first region includes a top surface and a side upper portion of the bottom electrode, and the second region includes a lower portion of the bottom electrode.

5. The method of claim 1, wherein a tilt is adjusted during the ion implantation process to extend the first region.

6. The method of claim 1, wherein the bottom electrode has one of a cylindrical-type structure including the top surface and the side surface or a pillar-type structure including the top surface and the side surface.

7. The method of claim 1, wherein the bottom electrode includes at least one selected from the group consisting of:
a metal, a metal nitride and a noble metal.

8. The method of claim 7, wherein the metal is selected from the group consisting of aluminum (Al), copper (Cu) and tungsten (W), the metal nitride is selected from the group consisting of titanium nitride (TiN), titanium aluminum nitride (TiAlN), titanium silicon nitride (TiSiN) and tantalum nitride (TaN) and the noble metal is selected from the group consisting of ruthenium (Ru), Iridium (Ir) and platinum (Pt).

9. The method of claim 1, further comprising:
forming a top electrode which covers the bottom electrode.

10. A method of forming a semiconductor device comprising:
forming a bottom electrode on a semiconductor substrate, wherein the bottom electrode has a first region including an inner surface, an outer surface and a top surface connecting the inner surface and the outer surface with each other and a second region which includes a lower portion of the bottom electrode;
performing a tilted ion implantation process by supplying ions to the first region of the bottom electrode, wherein the ions are not supplied to the second region of the bottom electrode by the tilted ion implantation process;
forming a dielectric layer uniformly covering the bottom electrode; and
forming a top electrode covering the bottom electrode,
wherein the formation of the dielectric layer is delayed at the first region than at the second region.

11. The method of claim 10, wherein during the tilted ion implantation process an amount of ions is supplied to the top surface, upper portions of the inner surface and the outer surface of the first region of the bottom electrode which is greater than an amount of ions supplied to lower portions of the inner surface and the outer surface of the first region of the bottom electrode, and wherein the formation of the dielectric layer is more delayed at the upper portion of the inner surface and the outer surface of the first region of the bottom electrode than at the lower portion of the inner surface of the first region of the bottom electrode.

12. The method of claim 10, wherein the forming of the bottom electrode comprises:
forming a first interlayer dielectric including a conductor on a semiconductor substrate;
forming a second interlayer dielectric on the first interlayer dielectric;
forming a contact plug that is electrically connected to the conductor through the second interlayer dielectric;
forming a mask layer on the second interlayer dielectric;
forming a molding layer on the mask layer;
patterning the molding layer and the mask layer to form a hole therethrough which exposes a top surface of the contact plug;
forming a conductive layer uniformly on the exposed top surface of the contact plug and sidewalls of the hole;
forming a sacrificial layer on the conductive layer to fill the hole; and successively planarizing the sacrificial layer and the conductive layer down to a surface of the molding layer to thereby foam the bottom electrode.

13. The method of claim 12, wherein prior to performing the tilted ion implantation process, the method further comprises:
exposing the inner surface and the outer surface of the first region of the bottom electrode by removing the molding layer and the sacrificial layer.

14. The method of claim 11, wherein the forming of the bottom electrode comprises:
forming a first interlayer dielectric including a conductor on the semiconductor substrate;
forming a second interlayer dielectric on the first interlayer dielectric;
forming a contact plug that is electrically connected to the conductor through the second interlayer dielectric;
forming a mask layer on the second interlayer dielectric;
forming a molding layer on the mask layer;
patterning the molding layer and the mask layer to form a hole therethrough which exposes a top surface of the contact plug;
forming a conductive layer to fill the hole;
planarizing the conductive layer down to a top surface of the molding layer, thereby forming the bottom electrode.

15. The method as set forth in claim 10, wherein the bottom electrode includes at least one selected from the group consisting of:
a metal, a metal nitride and a noble metal.

16. The method of claim 15, wherein the metal is selected from the group consisting of aluminum (Al), copper (Cu) and tungsten (W), the metal nitride is selected from the group consisting of titanium nitride (TiN), titanium aluminum nitride (TiAlN), titanium silicon nitride (TiSiN) and tantalum nitride (TaN) and the noble metal is selected from the group consisting of ruthenium (Ru), Iridium (Ir) and platinum (Pt).

17. The method of claim 10, wherein the process for forming the dielectric layer includes having a hydroxyl radical (OH) adsorbed to the inner surface, the outer surface and the top surface of the first region of the bottom electrode and chemically bound to a metal-organic precursor.

18. The method of claim 10, wherein the hydroxyl radical is adsorbed to the inner surface, the outer surface and the top surface of the first region of the bottom electrode and chemically bound to the metal-organic precursor to form the dielectric layer by supplying a source gas comprising the metal-organic precursor onto the bottom electrode, wherein the metal-organic precursor is tetrakis(ethylmethylamino) zirconium (Zr[N(CH₃)C₂H₅]₄; TEMAZ); and supplying a reaction gas comprising one of vapor (H₂O) or ozone (O₃) onto the bottom electrode after the source gas is supplied.

19. The method of claim 10, wherein the tilted ion implantation process is performed using a gas containing at least one selected from the group consisting of nitrogen (N), boron (B) and a combination thereof.
